(19) United States
(12) Patent Application Publication
(10) Pub. No.: US 2019/0257888 A1
(43) Pub. Date: Aug. 22, 2019

(54) MANAGING BATTERY CONSUMPTION OF A TELEMATICS CONTROL UNIT

(71) Applicant: Visteon Global Technologies, Inc., Van Buren Township, MI (US)

(72) Inventors: Nileshkumar H. Patel, Canton, MI (US); Husein Dakroub, Dearborn Heights, MI (US); Lambros B. Dimopoulos, Van Buren Township, MI (US)

(21) Appl. No.: 15/899,285

(22) Filed: Feb. 19, 2018

(51) Int. Cl. G01R 31/36; H04L 29/08; G05B 19/048; B60R 16/04; H04W 52/38; H04W 52/02

(52) U.S. Cl. CPC G01R 31/3689; H04L 67/12; H04W 52/0261; B60R 16/04; H04W 52/38; G05B 19/048

(57) ABSTRACT

A method for controlling a current consumption of a telematics control unit (TCU) is based on an estimated current consumption of an event during an ignition off condition of a vehicle includes estimating the current consumption of the event, determining a value of a software ammeter, and transitioning into a power mode based on the value.

### BACKGROUND

Telematics Control Units (TCU) are used to provide mobile communication technology in vehicles. The TCU is an embedded system on board the vehicle that controls the communications with other electronic systems of the vehicle and interprets and disperses the data as needed. The TCU consumes power to operate, even when the ignition of the vehicle is off and power resources are limited. A hardware ammeter can be used to monitor the power consumption; however, constantly monitoring current consumption using hardware is inefficient.

### SUMMARY

This section provides a general summary of the present disclosure and is not a comprehensive disclosure of its full scope or all of its features, aspects, and objectives.

Disclosed herein is a method for controlling a current consumption of a TCU based on an estimated current consumption of an event during an ignition off condition of a vehicle. The method includes estimating the current consumption of the event, determining a value of a software ammeter, and transitioning into a power mode based on the value.

Also disclosed herein is a method for predicting battery consumption of a TCU. The method includes determining an off condition of an ignition, determining that an event occurred, and determining a status of an embedded phone (EP). The method further includes estimating the battery consumption of the event, determining a value of a software ammeter, and transitioning to a power mode based on the value.

Also disclosed herein is a system for predicting battery consumption by a TCU in a vehicle. The system includes a non-transitory computer readable medium to store instructions of the system and a processor configured to execute the instructions. The processor is configured to determine an off condition of an ignition, determine that an event occurred, estimate the battery consumption of the system, determine a value of a software ammeter, and transition into a power mode based on the value.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is an illustrative block diagram depicting exemplary components of a system in accordance with one aspect of the present disclosure;

FIG. 2 is an illustrative graph depicting timing of power modes of the system in accordance with one aspect of the present disclosure;

FIG. 3 is an illustrative diagram depicting the current calculation of the system transitioning from an on mode to a standby mode in accordance with one aspect of the present disclosure;

FIG. 4 is an illustrative diagram depicting the current calculation of the system transitioning from a standby mode to an LPL mode in accordance with one aspect of the present disclosure;

FIG. 5 is an illustrative diagram depicting the current calculation of the system transitioning from the LPL mode to the standby mode in accordance with one aspect of the present disclosure;

FIG. 6 is an illustrative diagram depicting the current calculation of the system transitioning from a sleep mode to the standby mode in accordance with one aspect of the present disclosure;

FIG. 7 is an illustrative diagram depicting the current calculation of the system transitioning from any power mode to the on mode in accordance with one aspect of the present disclosure;

FIG. 8 is an illustrative diagram depicting the current calculation of the system transitioning from the standby mode to the sleep mode in accordance with one aspect of the present disclosure;

FIG. 9 is an illustrative flow chart a method of the system in accordance with one aspect of the present disclosure; and

FIG. 10 is an illustrative graph depicting the current consumption when a value of a software ammeter is greater than zero in accordance with one aspect of the present disclosure.

### DETAILED DESCRIPTION

The following description is merely exemplary in nature and is not intended to limit the disclosure in its application or uses. For purposes of clarity, the same reference numbers are used in the description and drawings to identify similar elements.

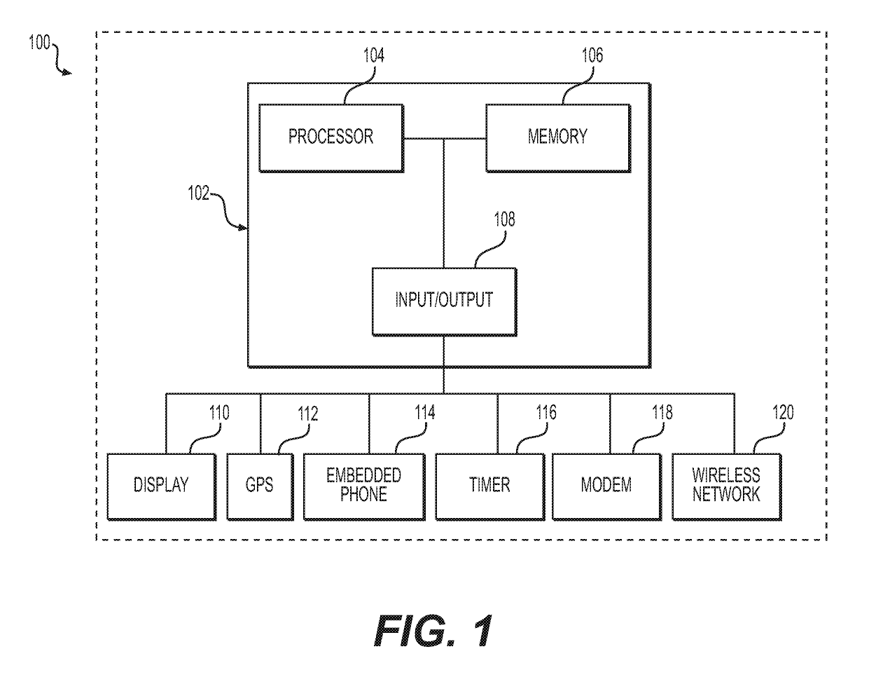

FIG. 1 is an illustrative block diagram depicting exemplary components of a system 100 in accordance with one aspect of the present disclosure. The system 100 can include additional and/or fewer components and is not limited to those illustrated in FIG. 1. The system 100 includes a Telematics Control Unit, or TCU 102. The TCU 102 includes various components such as at least one microprocessor or processor 104, a memory 106, and an input/output 108.

Through the input/output 108, the TCU 102 communicates with a display 110, a GPS 112, an embedded phone (EP) 114, a timer 116, a modem 118, and a wireless network 120. The TCU 102 can communicate with base stations of wireless networks 116 to provide telematics functionality for the vehicle, such as vehicle tracking, on-line navigation, emergency assistance, vehicle diagnostics, infotainment, internet access, telephone and voicemail services, etc. The TCU 102 can communicate to additional devices, such as an electronics control unit (ECU).

The processor 104 is a device that processes signals and performs general computing and arithmetic functions. The processor 104 can include multiple single and multicore processors, co-processors, and architectures.

The memory 106 can include a variety of memory, such as volatile memory and non-volatile memory. The memory 106 can also include a disk, such as but not limited to a flash memory card, a memory stick, a magnetic disk drive, a solid state disk drive, a CR-ROM, or a DVD ROM. The memory 106 can store a system that controls resources of a computing device and software that the processor 104 executes.

The processor 104 and memory 106 are operatively coupled. The processor 104 performs processes by executing software instructions stored by the memory 106. The processes can include capturing data of a type of action of the system 100. For example, the processes can include determining a call type. The processes can also include activating the modem 118 for a predetermined time based on the call type. The processes can further include managing power for the TCU 102. For example, every time the TCU 102 is required to perform an action, the timer 116 decrements the amount of time associated with the action. The timer 116 is then used to measure against a maximum allotted time for the activity when the ignition of the vehicle is in an off condition. When the time goes below a predetermined threshold, the system 100 transitions the TCU 102 from a standby mode 208 to a sleep mode 212.

The processor 104 and the memory 106 communicate through the input/output 108. The input/output 108 is a part of the system 100 and communicates with a variety of devices, such as the display 110, the GPS 112, the embedded phone 114, the timer 116, the modem 118, and the wireless network 120. The data captured various devices is input to processor 104 for processing and outputting for providing instructions or information to systems of the vehicle.

The memory 106 stores an algorithm having software parameters to estimate how much power is consumed during certain events. The algorithm is embedded in the software of the TCU 102 and processed by processor 104. The TCU 102 uses the timer 116 and a software ammeter (SW_Ammeter) to monitor estimated time from a predetermined time period. For example, the TCU 102 uses the timer 116, such as an LPL_Timer, and the SW_Ammeter to monitor the time (e.g. seven days) that the TCU 102 can spend in the LPL mode 210 after the ignition turns off. The processor 104 will subtract any time calculated by the SW_Ammeter that the TCU 102 spends in the standby mode 208 from the LPL_Timer.

Below is a table of power usage of the TCU 102 and current budget definitions. Table 1 also includes sample parameters used by the SW_Ammeter for current budget calculations.

TABLE 1

| Reference No. | Parameters | Definition |
|---|---|---|
| 4 | Current_Budget | The threshold Current Level which triggers |
| | | the TCU 102 to transition from LPL |
| | | mode 210 to Sleep Mode 212. |
| 4a | Remaining_Budget | Remaining budget that the TCU 102 has |
| | | available. This value changes every time the |
| | | TCU 102 enters in a lower power mode |
| | | (LPM, such as a low power listening mode |
| | | (LPL mode 210). |
| 5c | 7761_Average | The worst case current consumption of |
| | | the 7761 in EP 114 in standby mode 208. |
| 6 | 7761_Uptime | 7761_Uptime = (7761_ETime) − |
| | | (7761_STime) |
| 7 | 7761_STime | Timestamp of when 7761 enters standby |
| | | mode 208. |
| 8 | 7761_ETime | Timestamp right before 7761 exits standby |
| | | mode 208. |
| 10 | LPL_Timer | This is the time the TCU 102 will spend in |
| | | LPL mode 210/standby mode 208 before it |
| | | enters into sleep mode 212. |
| 11 | SW_Ammeter | The calculated time the TCU 102 has spent |
| | | in LPL mode 210 and standby mode 208 |
| | | during a call. This value changes every time |
| | | the TCU 102 enters into LPL mode 210. |
| 12 | Call_Time | The time that the TCU 102 has spent in a |
| | | voice call. |
| 13 | 7761_OnCall_Average | The worst case current consumption of |
| | | the 7761 and EP 114 during a voice call in |
| | | standby mode 208. |
| 15 | Listen_Time | The time that 7761 and EP 114 spend in LPL |
| | | mode 210. |
| 16 | 7761_LPM_Average | The worst case current consumption of 7761 |
| | | and EP 114 in LPL mode 210. |
| 17 | SW_Ammeter_Timer_Adjusted | The adjusted LPL_Timer based on the |
| | | SW_Ammeter calculation. This value |
| | | changes every time the TCU 102 enters in |
| | | LPL mode 210. |

The parameters in Table 1 include combinations of product requirements derived by performing various tests on the TCU 102 and/or the EP 114. The tests can include evaluating minimum and/or maximum values to determine ideal numeric values under various environments. The SW_Ammeter uses the ideal numeric values. Thereafter, if issues or system level changes are present, the value of the parameters can change, resulting in new ideal numeric values for the SW_Ammeter to use.

The display 110 is an embedded or onboard system of the vehicle. The display 110 broadly includes any form of electronic device, including both hardware and software components that enables a user to communicate with the vehicle. The user can use the display 110 to view or control vehicle functions such as to operate the GPS 112, place a voice call using the embedded phone 114, or another function (e.g. to unlock or lock vehicle door(s), play music, use the infotainment system, etc.).

The GPS 112 is an embedded or onboard system of the vehicle. The GPS 112 is a global positioning system unit that tracks the positions of the vehicle (i.e., the latitude and longitude values). The TCU 102 communicates with the GPS 112 and can use the position data of the vehicle for various functions or provide the data to other systems, such as navigation. The position data can be automatically provided to the TCU 102.

The embedded phone 114 is an embedded or onboard system of the vehicle. Embedded systems allow a user to connect to the vehicle remotely. In other words, it allows the user to access the vehicle when a user is not near the vehicle. For example, embedded systems allow a user to lock or unlock vehicle door(s) and find the vehicle on a virtual map. The TCU 102 communicates with the embedded phone 114 to provide information, such as automatic collision notifications or emergency crash notifications. The automatic collision notifications can be provided to a service provider, call center, or emergency contact. The embedded phone 114 can connect to a Cloud through a cellular network used for mobile phones by using an embedded cellular modem 118. When the vehicle is in the off condition, the embedded phone 114 can remain on. When the embedded phone 114 is on, the embedded phone 114 can be connected to the wireless network 120. The embedded phone 114 also looks for events that the TCU 102 would need to process. If the event occurs, the embedded phone 114 wakes up the processor 104. The embedded phone 114 can also include an alarm. The alarm can be used to wakeup components or systems of the vehicle, such as the processor 104, after a certain period of time.

The modem 118 is an embedded or onboard system in the vehicle. The modem 118 communicates with the TCU 102 as well as additional systems in the vehicle. The modem 118 handles automatic collision notifications and remote vehicle features. The modem 118 can continue to work after collisions. The modem 118 can use land-based cell towers for two-way communication. The modem 118 can be used for a variety of functions such as receiving navigation information and position data from the GPS 112. The modem 118 communicates with the embedded phone 114. For example, the modem 118 can be used to make voice calls. External antennas can be used to enhance the quality of the voice call.

The timer 116 is an embedded or onboard system in the vehicle. The TCU 102 communicates with the timer 116. The TCU 102 uses the timer 116 to predict or estimate how much current was consumed by the TCU 102 while the processor 104 and/or the ignition are turned off, for example in the LPL mode 210. When the TCU 102 is in the LPL mode 210, an event can occur that wakes up the TCU 102/processor 104. Each time such an event occurs, the timer 116 determines the amount of battery or current used. After a specified or predetermined amount of energy is used, the TCU 102 transitions from the LPL mode 210 to another mode, such as the sleep mode 212 or a complete shutdown, such as a deep sleep mode.

The TCU 102 can transmit messages and calls when it has access to the wireless network 120. The TCU 102 can access the wireless network 120 when a wireless transceiver is activated. When the ignition of the vehicle is in an off condition, the wireless transceiver can be periodically activated. For example, the wireless transceiver can receive communication, such as a voice call or SMS message, transmitted to the TCU 102 through the wireless network 120. When the ignition is in the off condition, components of the TCU 102, such as the display 110 or modem 118, can be inactivated to save power. The transceiver can inactivate after a period of time or after a condition occurs. The system 100 can include additional and/or fewer components and is not limited to those illustrated in FIG. 1.

In one embodiment, the system 100 predicts battery consumption by the TCU 102 in the vehicle. The system 100 includes a non-transitory computer readable medium to store instructions of the system 100 and the processor 104 configured to execute the instructions. For example, the processor 104 is configured to determine an off condition of an ignition, or an ignition off condition 202. The processor 104 is configured to receive a time and date from the EP 114. The EP 114 is coupled to the processor. The processor 104 is also configured to determine that an event occurred and estimate the battery consumption of the system 100. The processor 104 is further configured to determine a value of the SW_Ammeter and transition the TCU 102 into a power mode based on the value of the SW_Ammeter. The value of the SW_Ammeter is based on at least one of a remaining budget and the remaining budget less the estimated battery consumption of the system 100. The estimated battery consumption of the event includes an estimate of an event. The event can include at least one of a call, an idle, a SMS, and data. The value of the SW_Ammeter can also include a deduction of an EP adjustment made to the EP 114 based on the status of the EP 114. For example, the status of the EP 114 can include signal strength, output power, or temperature. Depending on the status of the EP 114, the EP 114 can consume power. Thus, the processor 104 is configured to provide EP adjustments to account for the current consumed by the EP 114. If the processor 104 determines that the value of the SW_Ammeter is greater than zero, the processor 104 is configured to set a wakeup alarm request for the EP 114, set the remaining budget to the value, store the time and date, and transition to the power mode. The power mode in this situation is the sleep mode 212. If the processor determines that the value of the SW_Ammeter is less than or equal to zero, the processor 104 is configured to transition the TCU 102 into the deep sleep mode.

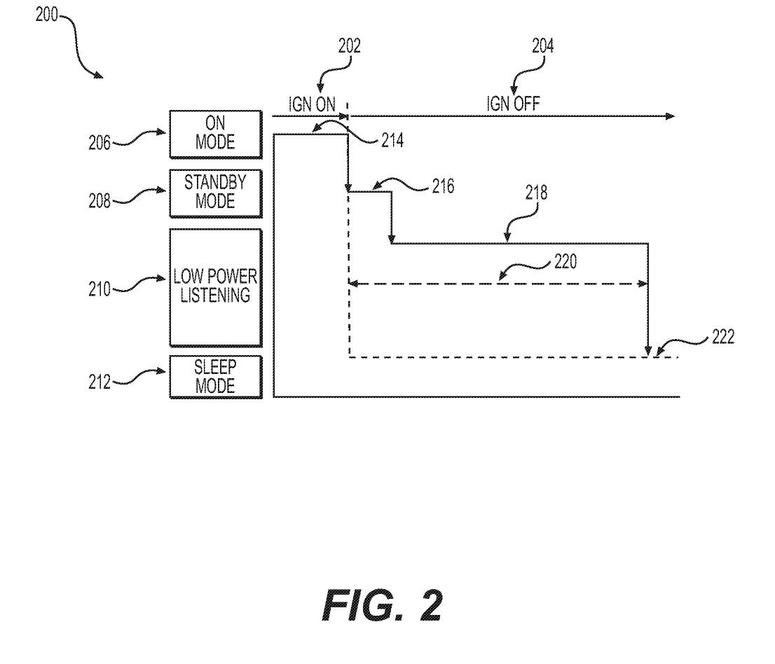

FIG. 2 is a graph 200 of an exemplary embodiment of system 100 that illustrates a low power listening (LPL) mode timing during certain conditions of the engine, such as during an ignition on condition 202 and an ignition off condition 204. During the ignition on condition 202, the TCU 102 is in the on mode 206 for a time period 214. After the vehicle transitions from the ignition on condition 202 to the ignition off condition 204, the EP 114 remains active and the TCU 102 transitions to another mode such as the standby mode 208 for a time period 216. After the time period 216 has elapsed and while in the ignition off condition 204 with the EP 114 remaining active, the TCU 102 transitions to the LPL mode 210. The TCU 102 remains in the LPL mode 210 for a time period 218.

As shown by a horizontal dotted line, a time period 220 includes the time from the start of the ignition off condition 204 until the TCU 102 transitions into the sleep mode 212. For example, the time period 220 is seven days unless the LPL_Timer is reduced by the SW_Ammeter. After the time period 216 has elapsed and while in the ignition off condition 204 with the EP 114 remaining active, the TCU 102 transitions to the sleep mode 212 for a time period 222. From the LPL mode 210, the TCU 102 suspends transitioning to the sleep mode 212 until the LPL_Timer expires. The LPL_Timer is initially set to the time period 220, for example, a time period of 7 days (10,080 minutes) when the ignition transitions from the ignition on condition 202 to the ignition off condition 204. The LPL_Timer can be set to alternative periods of time and can be changed after the initial setup. If the ignition transitions to back to the ignition on condition 202, the TCU 102 stops the LPL_Timer and resets it to the time period 220. The TCU 102 also resets the remaining budget. When the ignition transitions back to the ignition off condition 204, the TCU 102 begins decreasing the LPL_Timer.

The TCU 102 can not transition directly from the LPL mode 210 to the sleep mode 212, but rather transition from the LPL mode 210 to another standby mode briefly to preform shutdown actions for the TCU 102 prior to the final transition to the sleep mode 212. For clarity purposes, this feature has been omitted from FIG. 2.

During the ignition off condition 204 with the TCU 102 in a standby mode 208, the TCU 102 transitions from the standby mode 208 to the LPL mode 210, the TCU determines various parameters of the SW_Ammeter. For example, before transitioning out of the standby mode 208, the TCU 102 determines the time in of a call between the TCU 102 and a server and sets the Call_Time parameter. Before transitioning out of the standby mode 208, the TCU 102 determines the time spent in the LPL mode 210 and sets the Listen_Time parameter. Before transitioning out of the standby mode 208, the TCU 102 determines the time spent in the standby mode 208 and sets the 7761_Uptime parameter. The term “7761” refers to an ignition module (e.g. ignition module 304). The TCU 102 stores the SW_Ammeter to memory before transitioning to the LPL mode 210. While transitioning from the LPL mode 210 to the standby mode 208, the TCU 102 sets the Remaining_Budget parameter as follows:

Remaining_Budget=[SW_Ammeter (from memory)]

Before transitioning out of the standby mode 208, the TCU 102 determines the SW_Ammeter as follows:

SW_Ammeter=Remaining_Budget−[(Listen_Time*7761_LPM_Average)+(7761_Uptime*7761_Average)+(Call_Time*7761_OnCall_Average)]

If the TCU 102 enters from the standby mode 208 to the LPL mode 210, the TCU sets the LPL_Timer equal to the SW_Ammeter_Timer_Adjusted and sends the value to the EP 114. For example, the TCU 102 sets the LPL_Timer value as follows:

$$LPL\_Timer = SW\_Ammeter \_Timer \_Adjusted$$

$$SW\_Ammeter \_Timer \_Adjusted = ( SW\_Ammeter / 7761 \_LPM \_Average )$$

$$LPL\_Timer = SW\_Ammeter \_Timer \_Adjusted = 1000 mA / 68 mA h = 147.06 hours ( 8 , 823.52 minutes )$$

The TCU 102 enters into the LPL mode 210 when the value of the LPL_Timer has not expired and the SW_Ammeter has not depleted. However, when the value of the LPL_Timer expires (reaches zero), the TCU 102 shall process the shutdown of the EP 114 and the TCU 102 upon completion of the standby mode. This process transitions the TCU 102 to the sleep mode 212.

In other words, upon the ignition off condition, 204, and if no TCU 102 features are running, the TCU 102 will enter into the LPL mode 210. The TCU 102 turns off but the EP 114 remains on and is connected to the wireless network 120. The EP 114 is awake and looking for any events that the TCU 102 would need to process. If an event occurs, the EP 114 will wakeup the TCU 102.

When the TCU 102 enters the LPL mode 210, the TCU 102 sets and alarm on the EP 114 to wakeup the processor 104 after a period of time, such as 7 days (1149 mAh). If the TCU 102 is woken up from the LPL mode 210 (e.g. via SMS, etc.), the TCU 102 will provide various determinations and/or calculations. For example, the TCU 102 determines how long the TCU 102 spent in the LPL mode 210. The TCU 102 calculates the product of the LPL_Time and the LPL mode constant (e.g. LPL_Time*LPL mode constant). The LPL mode constant is defined by testing the worst case scenario. The TCU 102 also determines how long the TCU 102 spent processing the event or transaction. The TCU 102 calculates the product of a Transaction_Time and the transaction constant (e.g. Transaction_Time*transaction constant). The transaction constant is defined by testing the worst case scenario. The TCU 102 subtracts these calculations from the Remaining_Budget (e.g., from 1149 mAh). The TCU 102 sends a new alarm to the EP 114 to wake up the EP 114 sooner than the original period of time (e.g. 7 days). When the overall budget (e.g. 1149 mAh) is consumed, the TCU 102 shuts down at least the processor 104 and the EP 114 to basically prevent the TCU 102 from consuming vehicle battery.

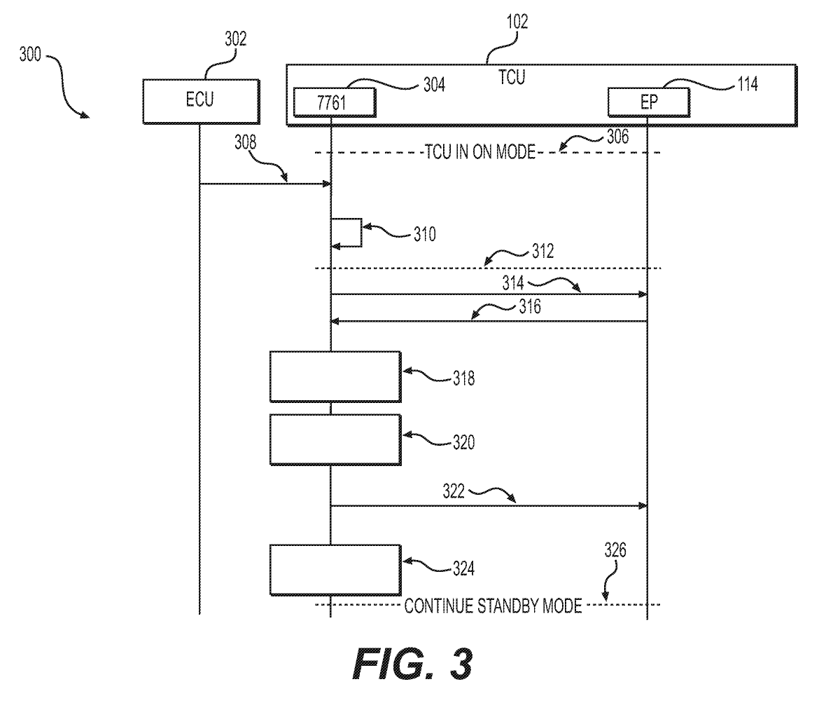

FIGS. 3-8 illustrate exemplary methods of how power usage calculations and monitoring is implemented in various power modes. The processes described in FIGS. 3-8 can include additional and/or fewer components and/or steps in an alternative order and are not limited to those illustrated in this disclosure.

FIG. 3 shows a process 300 for initiating the power usage calculation and monitoring for the SW_Ammeter during the ignition on condition 202 and transition to the standby mode 208. An electronic control unit or ECU 302 is any embedded system that controls one or more of the electrical system or subsystems in the vehicle. The ECU 302 communicates with the TCU 102. At step 306, the TCU 102 is in the on mode 206. In step 308, the ignition transitions from the ignition on condition 202 to the ignition off condition 204. The ECU 302 sends a corresponding signal to the TCU 102. The TCU 102 remains in the on mode 206 even after the transition of the ignition. The TCU 102 includes a 7761 ignition module, or ignition module 304 and the EP 114. The LPL_Timer 10 is turned on after the transition. The LPL_Timer monitors the time that the TCU 102 spends in the LPL/standby modes 210, 208 before the TCU 102 enters into the sleep mode 212. In other words, the LPL_Timer 10 runs and queries once it is ready to transition to LPL/Sleep Mode 210, 212 depending on a Voice Call or SMS service being active at the time of transition in step 308. If the transition occurred but the Voice/SMS allowed has not ended within the allocated timer usage, the TCU 102 can be allowed to continue for a certain type of service until the battery is drained. For example, if the type of service is an emergency call, the TCU 102 can continue to operate. At the time of service termination, if any leftover budget remains, the system 100 transitions to the LPL mode 210 or directly to the sleep mode 212.

At step 310, the TCU 102 transitions to the standby mode 208. At step 312, the TCU 102 is in the standby mode 208. At step 314, the TCU 102 requests the time and date from the EP 114. At step 316, the EP 114 sends a time and date response to the TCU 102. At step 318, the TCU 102 updates the LPL_Timer. At step 320, the TCU 102 updates the SW_Ammeter. At step 322, the TCU 102 sends a wakeup alarm request to the EP 114. The wakeup alarm request can include the date and time that the EP 114 should be woken up. The date can include the month, day, and year. The time can include the hour(s) and/or minute(s). At step 324, the TCU 102 sets or timestamps the 7761_STime. The 7761_STime is the timestamp of when 7761 enters the standby mode 208. At step 326, the TCU 102 continues to the standby mode 208. The TCU 102 can be in the standby mode 208 for a long time. While the TCU 102 is in the standby mode 206, the TCU 102 measures the power usage of both the ignition module 304 and of the EP 114. During this time, however, the TCU 102 does not compare the measurement against the Current_Budget in the standby mode 208 to allow for certain features to continue past the allotted budget.

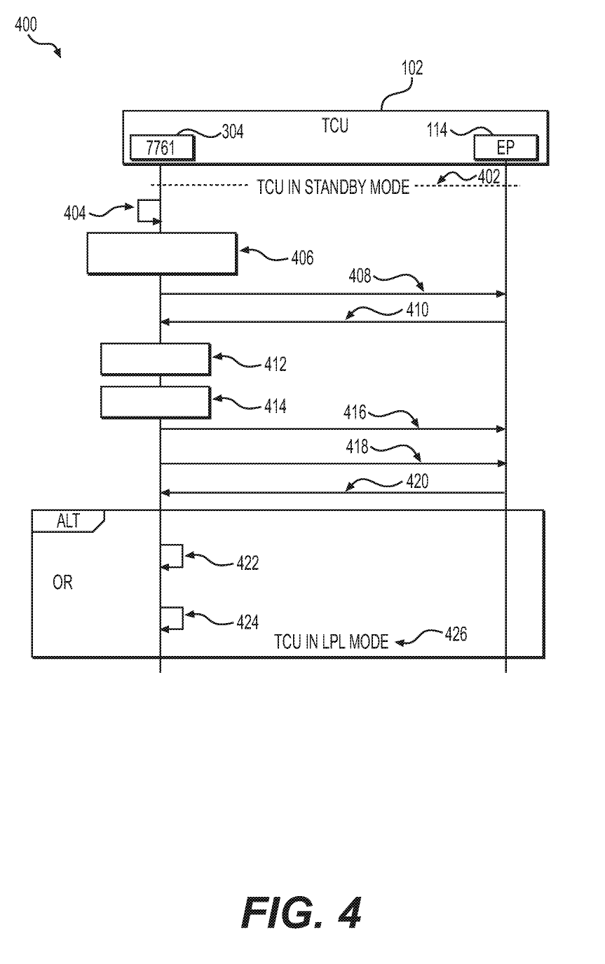

FIG. 4 shows a process 400 for handling the power usage calculation and monitoring for the SW_Ammeter when the TCU 102 transitions from the standby mode 208 to the LPL mode 210. In other words, FIG. 4 is a representation of a Voice/SMS service end (404). The system 100 asks a modem for the usage during the processes described in FIG. 3. The system 100 determines the current usage by the EP 114 and decides if the system 100 should transition to the LPL or sleep modes 210, 212.

At step 402, the TCU 102 is in the standby mode 208. In step 404, the TCU 102 sends a standby to LPL trigger. The trigger transitions the TCU 102 from the standby mode 208 to the LPL mode 210. The LPL_Timer 10 is turned on after the transition. The LPL_Timer monitors the time that the TCU 102 spends in the LPL/standby modes 210, 208 before the TCU 102 enters into the sleep mode 212. At step 406, the TCU 102 sets or timestamps the 7761_ETime. The 7761_ETime is the timestamp right before the 7761 exits the standby mode 208. The TCU 102 also determines the 7761_Uptime. The 7761_Uptime is determined by subtracting the 7761_STime from the 7761_ETime. At step 408, the TCU 102 requests the time and date from the EP 114. At step 410, the EP 114 sends a time and date response to the TCU 102. At step 412, the TCU 102 updates the SW_Ammeter. At step 414, the TCU 102 updates the LPL_Timer. At step 416, the TCU 102 sends a wakeup alarm request to the EP 114. The wakeup alarm request is a setting for a future event. For example, the wakeup alarm request can include the date and time that the EP 114 should be woken up. The date can include the month, day, and year. The time can include the hour(s) and/or minute(s).

At step 418, the TCU 102 performs a scan. The scan setting conserves the overall current usage by the EP 114. By default, the scan setting is a very low number, which allows the EP 114 to quickly scan the network 120 (e.g., in a few seconds). Because this scan uses more power, adding this scan setting to a scan setting with higher scan value (e.g., 420 seconds) reduces the number of time the EP 114 attempts to talk to the network 120, which saves power. The scan can last for a period of time, for example, 420 seconds. At step 420, the EP 114 provides an “OK” response to the TCU 102, indicating that the scan is okay. The OK response confirms that the EP 114 has accepted the new requested value of the network scan time while the system 100 is in the LPL mode 210. Steps 418, 420 allow the TCU 102 to control the scan time instead of using a fixed value (e.g., having a modem supplier managing the scan as a fixed value) to maintain similar functionality while reducing the power consumption. The scan time can be determined from numerous tests on the EP 114, as well as recommendations from a network provider. The scan time for given product can be determined from a one-time derived numeric value.

After step 420, the process 400 can proceed to step 422 or step 424, depending on the values of the LPL_Timer or the SW_Ammeter. The process 400 proceeds to step 422 if the LPL_Timer equals zero or the SW_Ammeter equals zero. At step 422, the TCU 102 sets the standby to sleep trigger. The TCU 102 can perform additional calculations, such as standby to sleep calculations. The process 400 then proceeds to step 426 with the TCU 102 in the LPL mode 210. Alternatively, if the LPL_Timer is greater than zero or the SW_Ammeter is greater than zero, then the process 400 proceeds to step 424. At step 424, the TCU 102 transitions to the LPL mode 210. At step 426, the TCU 102 is in the LPL mode 210.

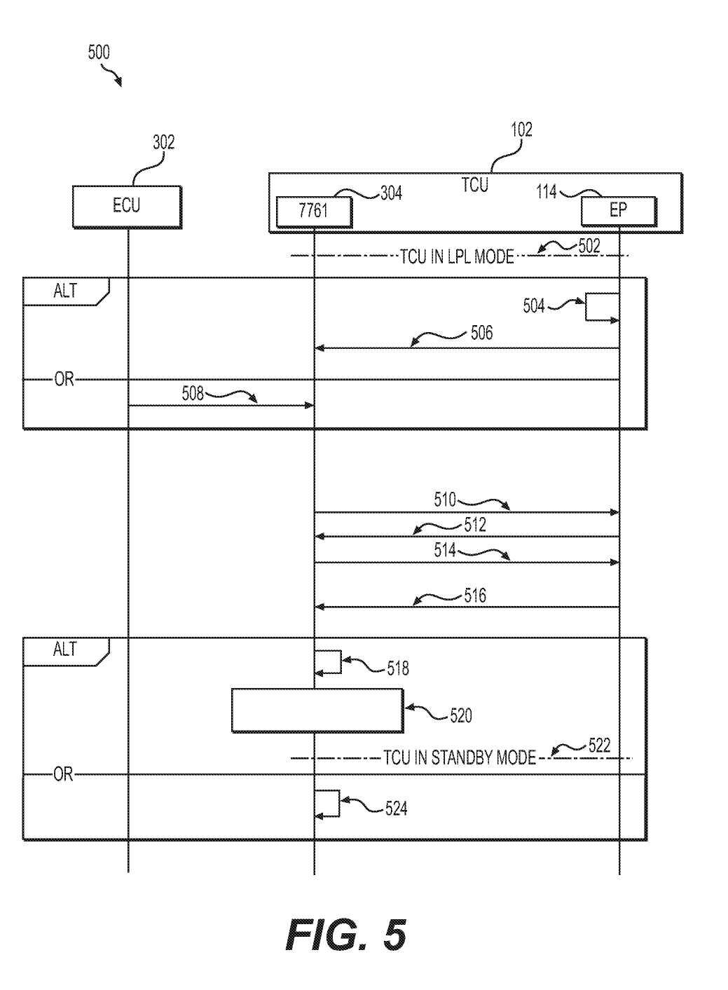

FIG. 5 illustrates a process 500 for reinitiating the power usage calculations for the ignition module 304. At step 502, the TCU 102 is in the LPL mode 210. The process 500 can proceed to either step 504 or step 508 depending on how the TCU 102 is woken up. If the TCU 102 is woken up by the EP 114, then the process 500 proceeds to step 504. At step 504, the TCU 102 determines if the LPL_Timer has expired or if a wakeup by the EP 114 occurs. If either occurs, then the EP 114 asserts a ring indicator (RI) at step 506. Alternatively, if the wakeup event occurs by the ECU 302, such as a BCAN, the process 500 proceeds to step 508. The ECU 302 is an integrated battery monitor, controller, and data-logger that can be installed on batteries of any type, voltage, and capacity. The ECU 302 is operatively coupled to the TCU 104 and/or the ECU 302. At step 508, the TCU 102 is woken up by the ECU 302. At this time, the Listen_Time can be activated. The Listen_Time is the time that the 7761 and the EP 114 spend in the LPL mode 210. After either step 506 or 508, the process 500 continues to step 510. At step 510, the TCU 102 requests the time and date from the EP 114. At step 512, the EP 114 sends a time and date response to the TCU 102. At step 514, the EP 114 requests a wakeup time. For example, the EP 114 requests an exact wakeup time. At step 516, the TCU 102 sends a wakeup alarm request to the EP 114. The wakeup alarm request can include the date and time that the ignition module 304 should be woken up. The date can include the month, day, and year. The time can include the hour(s) and/or minute(s). After step 516, the process 500 can proceed to step 518 or step 524. At step 518, the TCU 102 transitions from the LPL mode 210 to the other standby mode. At step 520, the TCU 102 sets or timestamps the 7761_STime, which is the timestamp for the time at which the 7761 304 enters the other standby mode. At step 522, the TCU 102 is in the standby mode. Alternatively, at step 524, the TCU 102 sets the standby mode to sleep trigger.

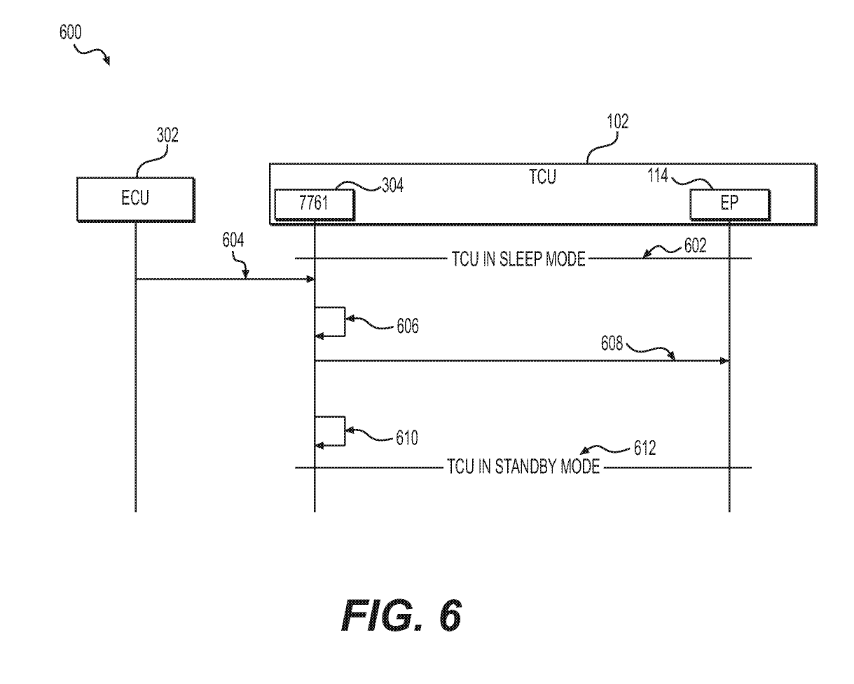

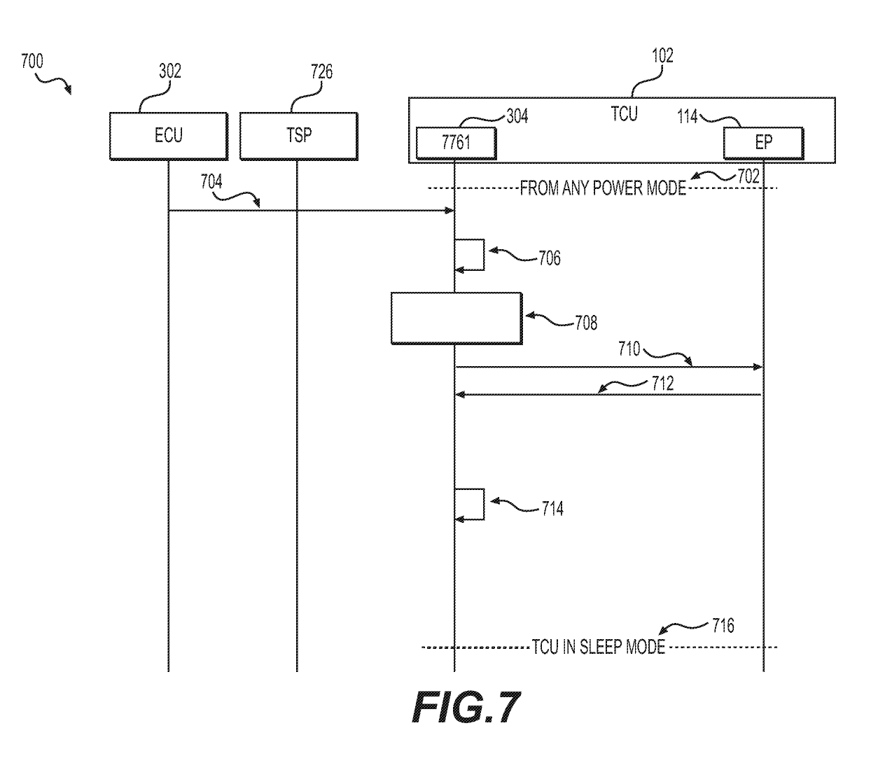

FIG. 6 illustrates a process 600 for handling the power usage calculations and monitoring when the TCU 102 transitions from the sleep mode 212 to the standby mode 208. At step 602, the TCU 102 is in the sleep mode 212. The ECU 302 provides a BCAN wakeup at step 604. The LPL_Timer monitors the time that the TCU 102 spends in the LPL/standby modes 210, 208 before the TCU 102 enters into the sleep mode 212. However, because process 600 is an ECU event and the system 100 is already in the sleep mode 212, the system 100 does not manage the LPL_Timer. Instead, the 7761 304 manages an internal timer. The internal timer can be set to a specific amount of time, such as to 3 minutes. The LPL_Timer is reactivated in FIG. 7. At step 606, the TCU 102 sends a signal for a 7761 bootup. At step 608, the TCU 102 turns on the EP 114. At step 610, the TCU 102 transitions to the standby mode 208. At step 612, the TCU 102 is in the standby mode 208.

FIG. 7 illustrates a process 700 for terminating the power usage calculation and monitoring. At step 702, the TCU 102 can be in any power mode such as the on mode 206, the standby mode 208, or the LPL mode 210. At step 704, the ECU 302 sends a signal to the ignition module 304 to turn the ignition from the ignition off condition 202 to the ignition on condition 206. At step 706, the TCU 102 transitions to the on mode 206, if it is not already in the on mode 206. At step 708, the TCU 102 stops the LPL_Timer. At step 710, the TCU 102 performs a scan on the EP 114. The scan can last for a certain period of time, such as for 30 seconds. The TCU 102 can set the 7761_STime, such as the default start value stored in the memory 106. At step 712, The EP 114 sends the OK signal. The TCU 102 can determine the 7761_Uptime, such as the default start value stored in the memory 106.

At step 714, if the TCU 102 is not transitioning from the sleep mode 212 to the on mode 206 and communication has been successfully received for this power-up cycle, then the process 700 skips steps 718 and 720 and proceeds to step 716. The SOC is a State of Charge used to notify a Telematics Service provider (TSP 726) that the TCU 102 and/or the EP 114 is available for communication (e.g., Voice/SMS/Data connections). This process is also used to notify the TSP 726 that TCU 102/EP 114 is not available for Services when the system 100 transitions from the standby or LPL modes 208, 210 to the sleep mode 212. At step 716, the TCU 102 is in the on mode 206.

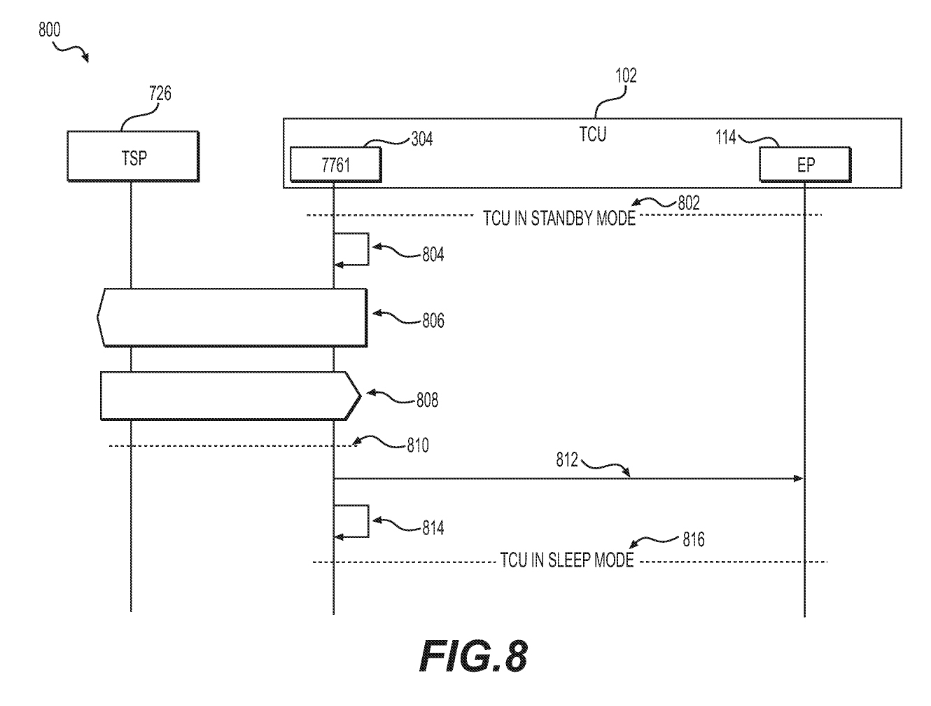

FIG. 8 illustrates a process 800 for handling the power usage calculations and monitoring when the TCU 102 transitions from the standby mode 208 to the sleep mode 212. At step 802, the TCU 102 is in the standby mode 208. At step 804, the TCU 102 sends a standby to sleep trigger and transitions from the standby mode. The LPL_Timer 10 is turned on after the transition. The LPL_Timer monitors the time that the TCU 102 spends in the LPL/standby modes 210, 208 before the TCU 102 enters into the sleep mode 212. In other words, if the LPL_Timer determines that the Voice/SMS service will exceed a timer/budget value, then the system 100 enters into the sleep mode 212.

Similar to steps 718, 720, and 722, at step 806, the TCU 102 provides the MO SMS-SOC Report to the TSP 726. The SOC Report can include various parameters and values, such as AppID=0x15, Action=1, and SOC_Indicator=2 Awake. At step 808, the TSP 726 sends the MT SMS-SOC ACK-MT, which can include various parameters and values, such as AppID=0x15 and Action=2. If necessary, the process 800 continues to step 810. At step 810, the TSP 726 sends the SMS-ACK Retry Strategy. At step 812, the TCU 102 turns off the EP 114. At step 814, the TCU 102 transitions to the sleep mode 212. At step 816, the TCU 102 is in the sleep mode 212. Process 800 assumes that the TCU 102 arrived in the standby mode while either executing either the standby mode to LPL mode sequence or the sleep mode to standby mode sequence and that while in the standby mode, the standby to sleep trigger in step 804 was encountered. A sleep mode flag is set to “ON” at the end of process 800.

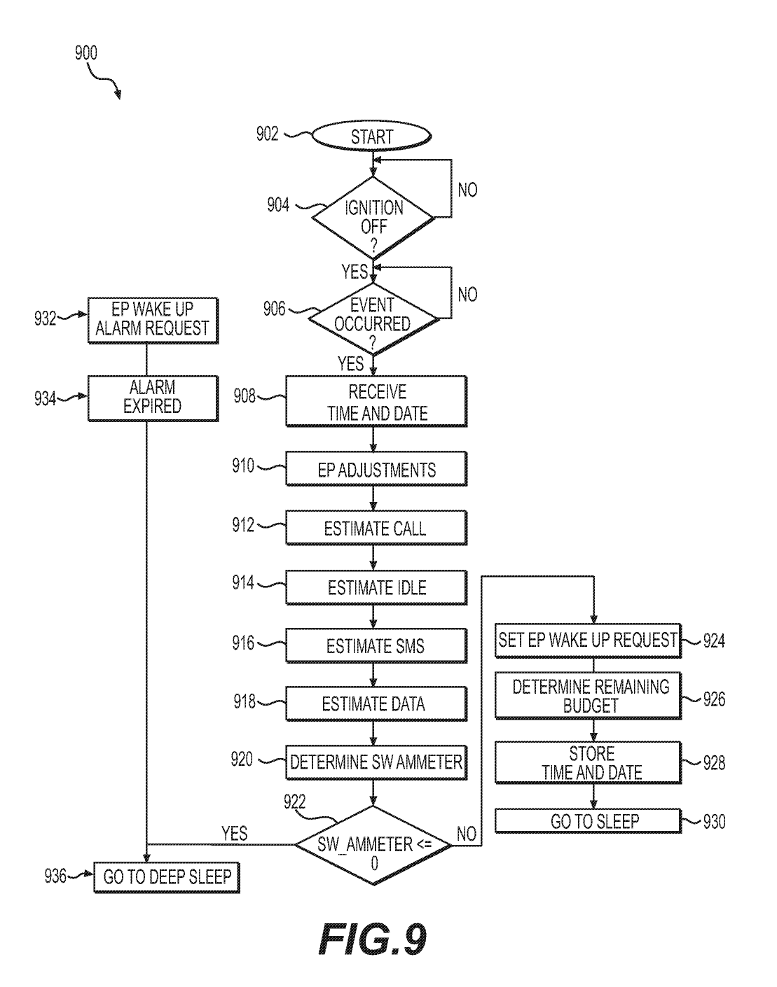

FIG. 9 is a flow chart of a method for monitoring battery or current consumption of the system 100. For example, the method 900 controls current consumption of the TCU 102 is based on an estimated current consumption of an event during the ignition off condition 204 of the vehicle. The method 900 of predicting battery consumption of the TCU 102 can occur after determining the off ignition condition 202 and that the event occurred, The method 900 includes various steps, such as estimating the current consumption of the event, determining a value of the software ammeter, and transitioning into a power mode based on the value. The method 900 also includes receiving a time and date from the EP 114, determining a status of the EP 114, and adjusting the current of the EP 114 based on the status. Estimating the current consumption of the event includes estimating the current consumption of at least one of a call, an idle, an SMS, and data. The method further includes setting an original budget and determining the Remaining_Budget based on the difference between the original budget and the current consumption. The value, therefore, is based on the difference between the Remaining_Budget and the current consumption. Current consumption can include the EP adjustment and the battery consumption of the event. If the value of the SW_Ammeter is less than or equal to zero, the TCU 102 transitions to the deep sleep mode. Alternatively, if the value is greater than zero, the method includes setting a wakeup alarm request for the EP 114, setting the Remaining_Budget to the value, storing the time and date, and transitioning into a power mode. For example, the TCU 102 transitions to the sleep mode 212. If after transitioning into the sleep mode 212, the system 100 detects the event, the system 100 powers on the TCU 102 to complete the event.

The method begins at step 902. At decision step 904, the system 100 determines if the ignition is in the ignition off condition 204. If the ignition off condition 204 is not detected, then the step loops until the condition is detected. After the ignition off condition is detected, the system 100 proceeds to decision step 906 to determine if an event has occurred. If an event is not detected, then the step loops until an event is detected. If an event is detected, then the system 100 proceeds to step 908.

At step 908, the system 100 receives a time and date from the EP 114. At step 910, the system 100 makes EP adjustments. The EP adjustments are current adjustments based on a status of the EP 114. The status can include various features or conditions of the EP 114, such as signal strength, output power, temperature, etc. Because of such features or conditions, the EP 114 can consume current. Thus, the system 100 accounts for the current consumption and makes the EP adjustments.

The system 100 provides various estimates, as shown in steps 910-918. At step 910, the system 100 estimates a call. The estimate call is a factor of a call time and a call constant (i.e., Estimate Call=Call_Time*Call_Constant). At step 912, the system 100 estimates an idle. The estimate idle is a factor of an idle time and an idle constant (i.e., Estimate Idle=Idle_Time*Idle_Constant). At step 914, the system 100 estimates a short message services, or an SMS. The estimate SMS is a factor of an SMS time and an SMS constant (i.e., Estimate SMS=SMS_Time*SMS_Constant). At step 916, the system 100 estimates data. The estimate data is a factor of a data time and a data constant (i.e., Estimate Data=Data_Time*Data_Constant).

At step 920, the system determines a value of the SW_Ammeter. The value is determined by subtracting the estimated current consumption in steps 910-918 from a remaining current budget, or Remaining_Budget. The Remaining_Budget is the current that the TCU 102 has available. This value of the Remaining_Budget changes every time the TCU 102 enters in LPM, such as LPL mode 210. The Remaining_Budget can be the current budget remaining from an original budget, such as a predetermined budget, after current consumption has been deducted. The Remaining_Budget can be the original budget if no current has been consumed. In other words, the SW_Ammeter is equal to the Remaining_Budget minus the EP Adjustments, the Estimate Call, the Estimate Idle, the Estimate SMS, and the Estimate Data.

At step 922, the system 100 determines the value of the SW_Ammeter. If the value is greater than zero, then the system 100 proceeds to step 924. At step 924, the system 100 sets an EP wakeup alarm request, or wakeup alarm request. The EP wakeup alarm request can be set to a specific date (e.g., [mm/dd/yy]) and time (e.g. [hh:mm]). At step 926, the system 100 sets the Remaining_Budget to the value of the SW_Ammeter. At step 928, the system 100 stores the time and date, for example, in the memory 106. At step 930, the system 100 goes to sleep or transitions to the sleep mode 212. During the sleep mode 212, the TCU 102 is powered off. Other components and/or systems can also be powered off, such as the display 110 (e.g. a vehicle interface). The EP 114 remains on during the sleep mode 212. If the EP 114 detects an event during the sleep mode 212, the EP 114 will power on the TCU 102. The TCU 102 will be able to complete the event. After the event, the method 900 can restart.

If the value of the SW_Ammeter is less than or equal to zero, then the system 100 goes to a deep sleep at step 936. During the deep sleep, the TCU 102 is completely powered off, which includes the EP 114.

Method 900 includes an alternative to steps 902-930. Method 900 can begin at step 932. At step 932, the system 100 sends the EP wakeup alarm request. At step 934, the system 100 determines that an alarm has expired. The alarm can be used to wakeup various components or systems of the vehicle, including the EP 114. If the alarm has expired, then the components or systems can no longer need to be active. The system 100 proceeds to step 936 and enters into the deep sleep mode. Method 900 can include additional and/or fewer steps in an alternative order and is not limited to those illustrated in this disclosure.

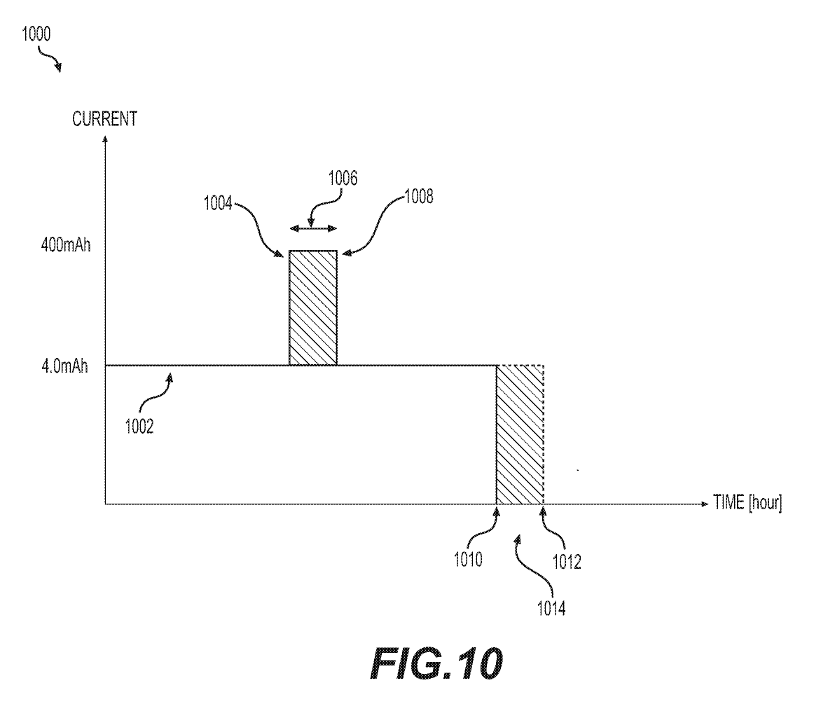

FIG. 10 is a graph 1000 of an example embodiment of process 900 illustrating when the SW_Ammeter is greater than zero. Every time the TCU 102 is required to perform an action or event, the battery timer, or timer 116 decrements the amount of time associated with the event. The timer 116 is then used to measure against the maximum allotted time for the event during the ignition off condition 204. When the timer 116 goes below a predetermined threshold, the system 100 transitions the TCU 102 from the LPL mode 210 to the sleep mode 212. At time period 1002, the TCU 102 is in the sleep mode 212. The TCU 102 draws power of 4.0 mAh of current. At time 1004, and event occurred and the TCU 102 increased its power draw to 400 mAh. During time period 1006, the TCU 102 continued to draw 400 mAh of current. For example, the event was that a user has requested to lock doors of the vehicle via a smart phone app. The time period 1006 lasts for three minutes. The current consumed during this event was 20 mAh. The calculation for the current consumption is 400 mAh*3 min*(1 hr/60 min)=20 mAh. The TCU 102 had estimated that the event would consume 20 mAh of current. At time 1008, the event has ended and the current consumption drops to the current consumption level before the event. The TCU 102 returns to the sleep mode 212 and draws 4.0 mAh of current. At time 1010, the TCU 102 sets an adjusted wakeup alarm request for the EP 114. An original wakeup alarm is adjusted due to the estimated current consumed. The TCU 102 determines that the Remaining_Budget equals 115 hours (4.8 days) or 460 mAh. The original wakeup alarm would have been at time 1012 had the event not occurred. The starting budget is 120 hours (5 days) or 480 mAh. The 20 mAh consumed during the event at consumption 1014 is subtracted from the starting budget to determine the adjusted wakeup alarm. At time 1012, the TCU 102 transitions to the sleep mode 212. Although the TCU 102 is powered off as well as the display 110 (e.g. vehicle interface), the EP 114 remains on. Thus, the system 100 consumes at least some current. If the EP 114 detects an event, it will power on the TCU 102 to complete the event. Alternatively, the TCU system 100 can go into a deep sleep at time 1012 or at another time. When the system 100 is in a deep sleep, the TCU 102 and the EP 114 are completely powered off.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. A method for controlling a current consumption of a telematics control unit (TCU) based on an estimated current consumption of an event during an ignition off condition of a vehicle, comprising:
estimating the current consumption of the event;
determining a value of a software ammeter; and
transitioning into a power mode based on the value.

2. The method of claim 1, further comprising:
receiving a time and date from an embedded phone; and
determining a status of the embedded phone.

3. The method of claim 2, further comprising:
adjusting the current of the embedded phone based on the status.

4. The method of claim 1, wherein estimating the current consumption of the event includes
estimating the current consumption of at least one of a call, an idle, an SMS, and data.

5. The method of claim 1, further comprising:
setting an original budget; and
determining a remaining budget based on the difference between the original budget and the current consumption.

6. The method of claim 5, wherein determining the value is based on the difference between the remaining budget and the current consumption.

7. The method of claim 1, further comprising:
setting a wakeup alarm request for the embedded phone.

8. The method of claim 1, further comprising:
determining that the value is greater than zero;
setting the remaining budget to the value.

9. The method of claim 8, further comprising:
storing the time and date.

10. The method of claim 1, wherein the transitioning into a power mode includes transitioning to at least one of a sleep mode and a deep sleep mode.

11. The method claim 1, further comprising:
determining that the value is greater than zero;
transitioning into a sleep mode;
detecting the event; and
powering on the TCU to complete the event.

12. A method for predicting battery consumption of a telematics control unit (TCU), comprising:
determining an off condition of an ignition;
determining that an event occurred;
determining a status of an embedded phone (EP);
estimating the battery consumption of the event;
determining a value of a software ammeter; and
transitioning to a power mode based on the value.

13. The method of claim 12, wherein if determining the value is to a value of less than or equal to zero, the method further comprises:
setting putting the TCU to a deep sleep mode.

14. The method of claim 12, wherein if determining the value is to a value of greater than zero, the method further comprises:
setting an EP walk-up request;
setting a remaining current budget;
storing the time and the date; and
transitioning the TCU to a sleep mode.

15. The method of claim 12, further comprising:
determining an EP adjustment based on the status of the EP.

16. The method of claim 15, wherein determining the value of the software ammeter is based on a Remaining_Budget less the EP adjustment and the battery consumption of the event.

17. A system for predicting battery consumption by a telematics control unit (TCU) in a vehicle, comprising:
a non-transitory computer readable medium to store instructions of the system; and
a processor configured to execute the instructions, the processor being configured to:
determine an off condition of an ignition;
determine that an event occurred;
estimate the battery consumption of the system;
determine a value of a software ammeter; and
transition into a power mode based on the value.

18. The system of claim 17, wherein the value of the software ammeter is based on at least one of a remaining budget and the remaining budget less the estimated battery consumption of the system.

19. The system of claim 18, wherein the estimated battery consumption includes an estimate of at least one of a call, an idle, a SMS, and data.

20. The system of claim 17, wherein the processor is further configured to:
receive a time and date from an embedded phone, the embedded phone being coupled to the processor;
determine that the value is greater than zero;
set a wakeup alarm request for the embedded phone;
set a remaining budget to the value;
store the time and date; and
transition to the power mode, wherein the power mode is a sleep mode.
